(19) United States
(12) Patent Application Publication
(10) Pub. No.: US 2023/0327212 A1
(43) Pub. Date: Oct. 12, 2023

(54) LITHIUM BATTERY AND MANUFACTURING METHOD THEREOF

(71) Applicant: Chung Yuan Christian University, Taoyuan City (TW)

(72) Inventors: Wei-Jen Liu, Taoyuan City (TW); Tzu-Hsin Tseng, Taoyuan City (TW)

(73) Assignee: Chung Yuan Christian University, Taoyuan City (TW)

(21) Appl. No.: 17/751,700

(22) Filed: May 24, 2022

(30) Foreign Application Priority Data
Apr. 12, 2022 (TW) 111113813

(51) Int. Cl. H01M 10/0585; H01M 10/052; H01M 4/62; H01M 4/66; H01M 4/04; H01M 4/525; H01M 4/505; C23C 14/06; C23C 14/34

(52) U.S. Cl. CPC H01M 10/0585; H01M 10/052; H01M 4/625; H01M 4/661; H01M 4/0426; H01M 4/0404; H01M 4/525; H01M 4/505; C23C 14/0617; C23C 14/34; H01M 2004/028

(57) ABSTRACT

A lithium battery includes a positive electrode, wherein the positive electrode includes a positive electrode sheet and a protective layer. The positive electrode sheet includes an active substance, a conductive additive, a binder, a current collector, or a combination thereof. The protective layer is disposed on the positive electrode sheet. A material of the protective layer is titanium nitride. A manufacturing method of a lithium battery is also provided.

### CROSS-REFERENCE TO RELATED APPLICATION

This application claims the priority benefit of Taiwan application serial no. 111113813, filed on Apr. 12, 2022. The entirety of the above-mentioned patent application is hereby incorporated by reference herein and made a part of this specification.

### BACKGROUND OF THE INVENTION

### Field of the Invention

The invention relates to a battery and a manufacturing method thereof, and in particular, to a lithium battery and a manufacturing method thereof.

### Description of Related Art

In recent years, electric vehicles (EVs) have become more and more popular, and automotive lithium batteries have attracted much attention due to their high energy density, high discharge voltage, and better power output stability. However, lithium batteries for vehicles currently need to be used in high temperature environments (such as 55° C.), so safety and high temperature stability and the like are also important considerations.

### SUMMARY OF THE INVENTION

The invention provides a lithium battery and a manufacturing method thereof that may effectively improve safety and high-temperature stability while improving performance.

A lithium battery of the invention includes a positive electrode, wherein the positive electrode includes a positive electrode sheet and a protective layer. The positive electrode sheet includes an active substance, a conductive additive, a binder, a current collector, or a combination thereof. The protective layer is disposed on the positive electrode sheet. A material of the protective layer is titanium nitride (TiN).

In an embodiment of the invention, the active substance includes LiNi_{0.6}Co_{0.2}Mn_{0.2}O₂, LiN_{0.8}Co_{0.1}Mn_{0.1}O₂, LiCoO₂, LiNi_{0.9}Co_{0.05}Mn_{0.05}O₂, LiNi_{0.5}Co_{0.3}Mn_{0.2}O₂, LiFePO₄, xLi₂MnO₃ (1−x)·Li(Co,Ni,Mn)O₂, or a combination thereof.

In an embodiment of the invention, the conductive additive includes flake graphite, carbon black, carbon nanotubes, graphene, carbon fiber, or a combination thereof, and the adhesive includes polyvinylidene fluoride (PVDF), carboxymethyl cellulose (CMC), styrene-butadiene rubber (SBR), polyimide (PI), polyvinyl alcohol (PA), or a combination thereof, and the current collector includes aluminum foil.

A manufacturing method of a lithium battery of the invention at least includes the following steps. A positive electrode sheet is provided. The positive electrode sheet is placed into a plasma-assisted physical deposition equipment, wherein the plasma-assisted physical deposition equipment includes a cavity, and the cavity has a titanium sputtering target. A plasma treatment process is performed on the positive electrode sheet to form a protective layer on the positive electrode sheet, wherein the plasma treatment process at least includes the following steps. The titanium sputtering target is bombarded with gas ions in the cavity to form titanium ions. Nitrogen is introduced into the cavity to make the titanium ions react with the nitrogen to form the protective layer.

In an embodiment of the invention, a process time of the plasma treatment process ranges from 1 minute to 100 minutes.

In an embodiment of the invention, a process temperature of the plasma treatment process ranges from 0° C. to 100° C.

In an embodiment of the invention, a process pressure of the plasma treatment process is at least less than 0.001 Torr.

In an embodiment of the invention, the manufacturing method of the lithium battery further includes applying a voltage to the titanium sputtering target to generate a plasma in the cavity to form the gas ions.

In an embodiment of the invention, the manufacturing method of the lithium battery further includes introducing argon gas and the nitrogen into the cavity to generate the gas ions.

In an embodiment of the invention, the manufacturing method of the lithium battery further includes the following steps. A current collector is provided, a slurry is coated on the current collector, and a drying process is performed to form the positive electrode sheet. In particular, the slurry includes at least the following manufacturing steps. A solvent is mixed with a binder to form a first solution. A conductive additive and an active substance are added to the first solution.

Based on the above, via the combination of the positive electrode and a titanium nitride protective layer (formed by the plasma treatment process (physical vapor deposition process)), safety and high-temperature stability of the lithium battery of the invention may be effectively improved while improving performance thereof.

In order to make the aforementioned features and advantages of the disclosure more comprehensible, embodiments accompanied with figures are described in detail below.

### BRIEF DESCRIPTION OF THE DRAWINGS

FIG. 1A is a schematic block diagram of a lithium battery undergoing a plasma treatment process according to an embodiment of the invention.

FIG. 1B is a flowchart of a manufacturing method of a lithium battery according to an embodiment of the invention.

FIG. 2 is an XRD diffraction pattern of the Examples and the Comparative example.

FIG. 3A and FIG. 3B are TEM images of an example.

FIG. 3C is a line scan enlarged view of the circled portion of FIG. 3B.

FIG. 3D is an elemental distribution diagram of the line scan of FIG. 3B.

FIG. 4A, FIG. 4B, FIG. 4C, and FIG. 4D are XPS (Ti spectrum, N spectrum, C spectrum, O spectrum) surface analysis diagrams of the Examples and the Comparative example, respectively.

FIG. 5A and FIG. 5B are graphs of voltage versus capacitance of the Examples and the Comparative example, respectively.

FIG. 6A and FIG. 6B are graphs of capacitance versus cycle number of the Examples and the Comparative example, respectively.

FIG. 7A and FIG. 7B are graphs of Coulomb efficiency versus cycle number of the Examples and the Comparative example, respectively.

FIG. 8A and FIG. 8B are graphs of capacitance and voltage differential (dQ/dV) versus voltage of the Examples and the Comparative example, respectively.

FIG. 9 is a graph of capacitance versus cycle number of the Examples and the Comparative example, respectively.

FIG. 10A and FIG. 10B are graphs of the imaginary part (Zᵢₘ) versus the real part (Zᵣₑ) of the impedance spectra of the Examples and the Comparative example, respectively.

FIG. 11A and FIG. 11B are graphs of current versus voltage of an Example and the Comparative example, respectively.

FIG. 12A and FIG. 12B are graphs of current versus scan rate of an Example and the Comparative example, respectively.

FIG. 13 is a graph of heating rate versus temperature of an Example and the Comparative example.

FIG. 14A and FIG. 14B are SEM images of the Examples and the Comparative example, respectively.

FIG. 15A, FIG. 15B, FIG. 15C, and FIG. 15D are XPS (F spectrum, N spectrum, O spectrum, P spectrum) surface analysis diagrams of the Examples and the Comparative example, respectively.

### DESCRIPTION OF THE EMBODIMENTS

To make the contents of the invention more easily understood, embodiments are provided below as examples of the plausibility of implementation of the invention. For the sake of clarity, many of the practical details are described together in the following description. However, it should be understood that, the practical details should not be used to limit the invention. In other words, in some embodiments of the invention, these practical details are not necessary.

Unless otherwise stated, all of the terminology used in the present specification (including technical and scientific terminology) have the same definition as those commonly understood by those skilled in the art of the invention.

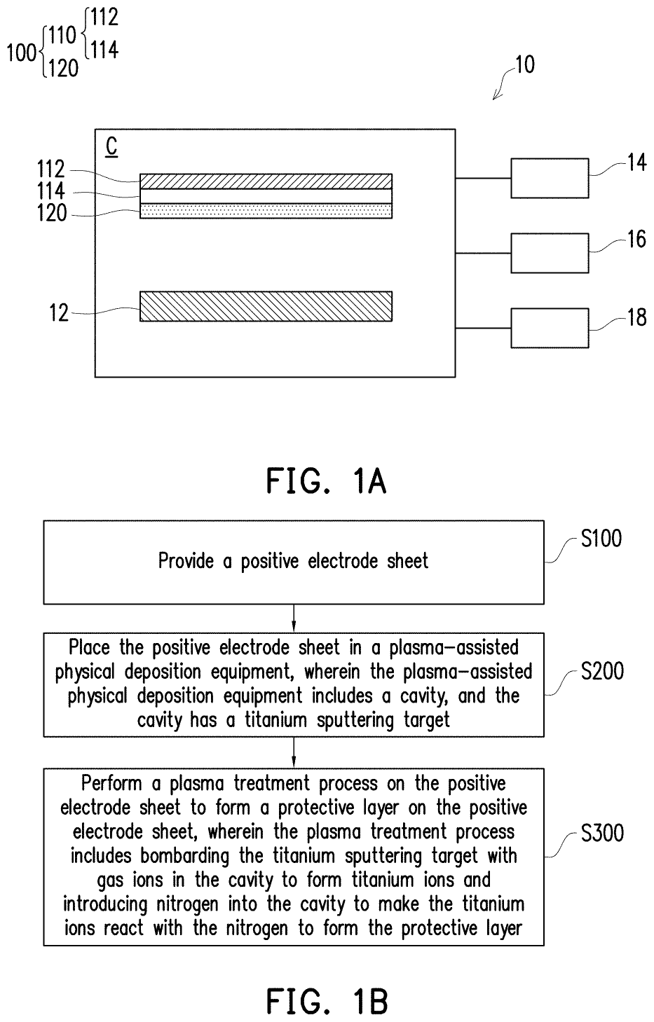

FIG. 1A is a schematic block diagram of a lithium battery undergoing a plasma treatment process according to an embodiment of the invention. FIG. 1B is a flowchart of a manufacturing method of a lithium battery according to an embodiment of the invention.

Please refer to FIG. 1A and FIG. 1B, the following describes the main flow of the manufacturing method of a lithium battery of an embodiment of the invention by using the drawings. First, a positive electrode sheet 110 is provided (step S100). Next, the positive electrode sheet 110 is placed in a plasma-assisted physical deposition equipment 10, wherein the plasma-assisted physical deposition equipment 10 includes a cavity C, and the cavity C has a titanium sputtering target 12 (step S200). Next, a plasma treatment process is performed on the positive electrode sheet 110 to form a protective layer 120 on the positive electrode sheet 110, wherein the plasma treatment process includes bombarding the titanium sputtering target 12 with gas ions in the cavity C to form titanium (Ti) ions and introducing nitrogen (N₂) into the cavity C, to react the titanium ions and nitrogen to form the protective layer 120 (step S300).

The manufacture of the positive electrode 100 of the lithium battery is substantially completed via the above steps. In the present embodiment, the lithium battery may include a positive electrode 100, wherein the positive electrode 100 includes the positive electrode sheet 110 and the protective layer 120 disposed on the positive electrode sheet 110. Here, the positive electrode sheet 110 includes an active substance, a conductive additive, a binder, a current collector, or a combination thereof, and the material of the protective layer is titanium nitride. Accordingly, via the combination of the positive electrode 110 and the titanium nitride protective layer 120 (formed by the plasma treatment process (physical vapor deposition process)), safety and high-temperature stability of the lithium battery of the present embodiment may be effectively improved while improving performance thereof.

In some embodiments, the plasma-assisted physical deposition equipment 10 further includes a nitrogen gas source 14 for supplying nitrogen. Moreover, the plasma-assisted physical deposition equipment 10 further includes an argon gas source 16 for supplying argon gas. In other words, argon gas may be introduced into the cavity C to generate the gas ions, but the invention is not limited thereto, and the argon gas source may be replaced by any other suitable inert gas source.

In some embodiments, the feed flow rate of introducing argon gas is equal to the feed flow rate of introducing nitrogen. In other words, the feed flow rate of introducing argon gas and the feed flow rate of introducing nitrogen may be both 30 sccm (standard cubic centimeter per minute). Therefore, the stability of the plasma film formation may be effectively improved by designing the ratio of argon gas to nitrogen, but the invention is not limited thereto.

In some embodiments, the process time of the plasma treatment process ranges from 1 minute to 100 minutes, the process temperature ranges from 0° C. to 100° C., and the process pressure is at least less than 0.001 Torr, but the invention is not limited thereto.

In some embodiments, the plasma-assisted physical deposition equipment 10 further includes a voltage applying portion 18 for applying a voltage to the titanium sputtering target 12 to generate plasma in the cavity C to form the gas ions, but the invention is not limited thereto.

In some embodiments, before the introduction of the argon gas and nitrogen, the air pressure in the cavity C may be made 10′ Torr or less via a general oil-pressure motor and a turbo pump, so as to avoid impurities in the cavity C, but the invention is not limited thereto.

In some embodiments, after passing argon gas and nitrogen and before starting to calculate the process time, the cavity C may be pre-ventilated for 2 minutes (the parameter setting is preferably at the working pressure of about 4.5×10⁻³ Torr, and the power is set at 350 V), to ensure stable plasma quality and no impurities in the cavity, then the predetermined rotation speed (for example, 10 rpm) is set and then the calculation of process time is started, but the invention is not limited thereto.

In some embodiments, the positive electrode sheet 110 may be manufactured by the following steps. First, a current collector 112 is provided. Next, a slurry 114 is coated on the current collector 112, wherein the slurry 114 may be formed by mixing a solvent and a binder to form a first solution, and then adding a conductive additive and an active substance into the first solution. Then, a drying process (removing moisture in the slurry 114) is performed to form the positive electrode sheet 110. Here, the solvent may be N-methylpyrrolidone (NMP).

In some embodiments, the current collector 112 and the slurry 114 are coated.

In some embodiments, after the solvent and the binder are mixed and the conductive additive and active substance are added to the first solution, the mixture may be stirred with a magnet or shaken by an ultrasonic oscillator in order to improve the mixing and dispersibility of materials. For example, after the solvent and the binder are mixed, the mixture may be uniformly stirred with a magnet for half an hour, and the conductive additive and the active substance may be uniformly stirred and left overnight after the first solution, then placed in an ultrasonic oscillator for 10 minutes and then continued to be stirred, but the invention is not limited thereto.

In some embodiments, the ratio of active substance to carbon black to binder is, for example, 8:1:1, but the invention is not limited thereto.

It should be noted that the positive electrode sheet 110 of the invention is not limited to the manufacturing steps, and the manufacturing steps and ratio of the positive electrode sheet 110 may be determined according to actual design requirements.

In some embodiments, the active substance includes LiNi_{0.6}Co_{0.2}Mn_{0.2}O₂, LiNi_{0.8}Co_{0.1}Mn_{0.1}O₂, LiCoO₂, LiNi_{0.9}Co_{0.05}Mn_{0.05}O₂, LiNi_{0.5}Co_{0.3}Mn_{0.2}O₂, LiFePO₄, xLi₂MnO₃ (1−x)·Li(Co,Ni,Mn)O₂, or a combination thereof. Since nickel (Ni) has the advantage of high energy density, but at the same time, the higher the content of nickel (Ni), the more unstable the lithium battery is, under the design of using the active substance and the titanium nitride protective layer 120, the protection function of the titanium nitride protective layer 120 may be further highlighted, so that the lithium battery has good stability in both normal-temperature environment and high-temperature environment, but the invention is not limited thereto.

In some embodiments, the conductive additive includes flake graphite, carbon black, carbon nanotubes, graphene, carbon fiber, or a combination thereof, and the adhesive includes polyvinylidene fluoride, carboxymethyl cellulose, styrene-butadiene rubber, polyimide, polyvinyl alcohol, or a combination thereof, and the current collector includes aluminum foil (may be carbon-coated aluminum foil), but the invention is not limited thereto.

It should be mentioned that, other unexplained compositions and specifications of the lithium battery should be obtained by those of ordinary skill in the art to which the invention pertains according to any content included in the spirit and scope of the appended claims, and will not be repeated herein.

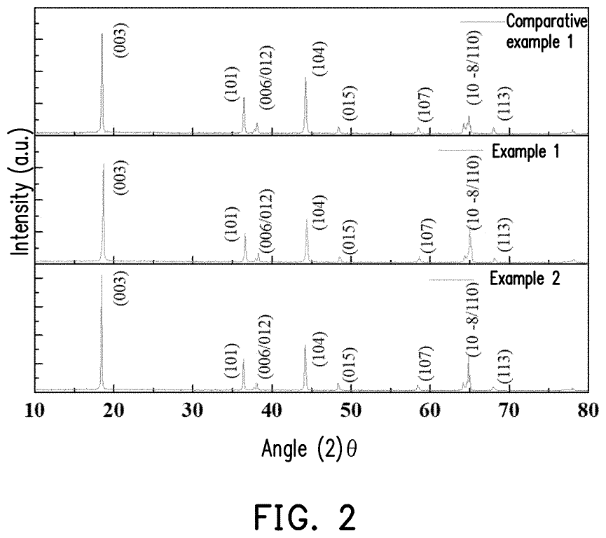

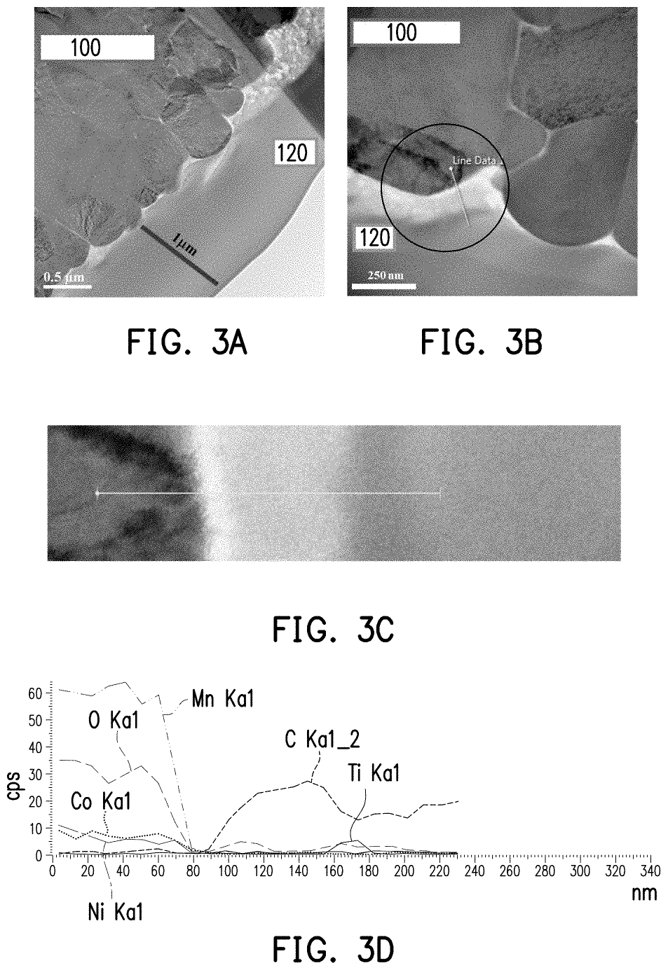

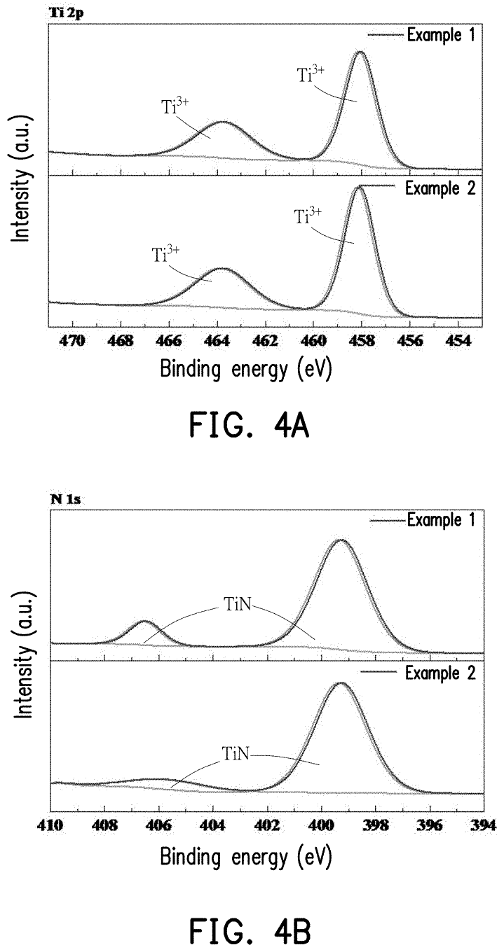

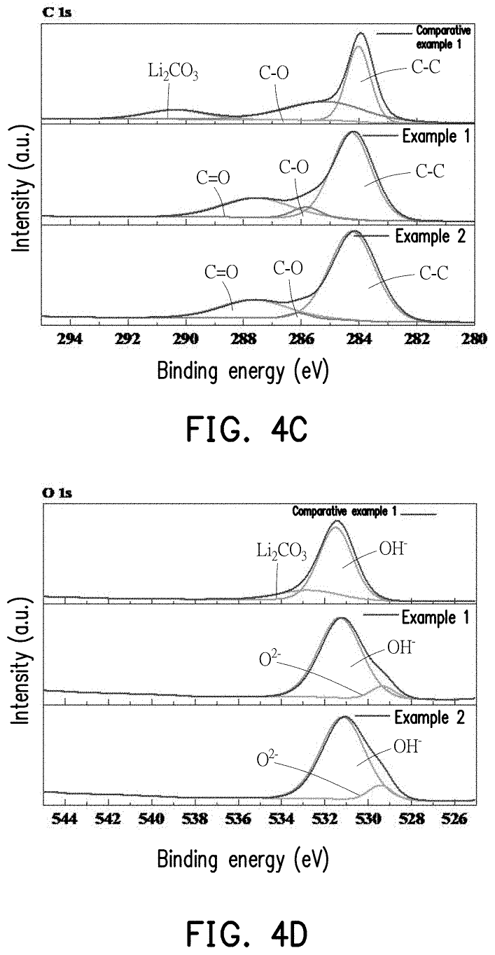

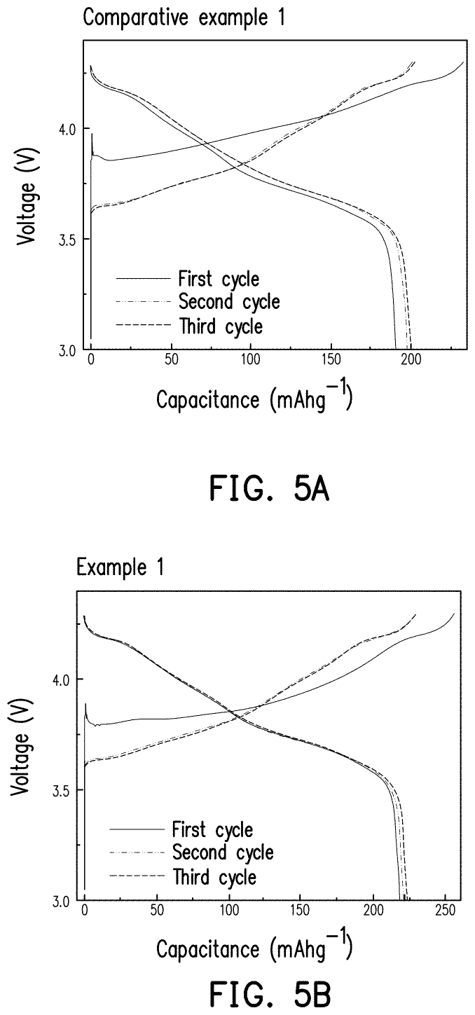

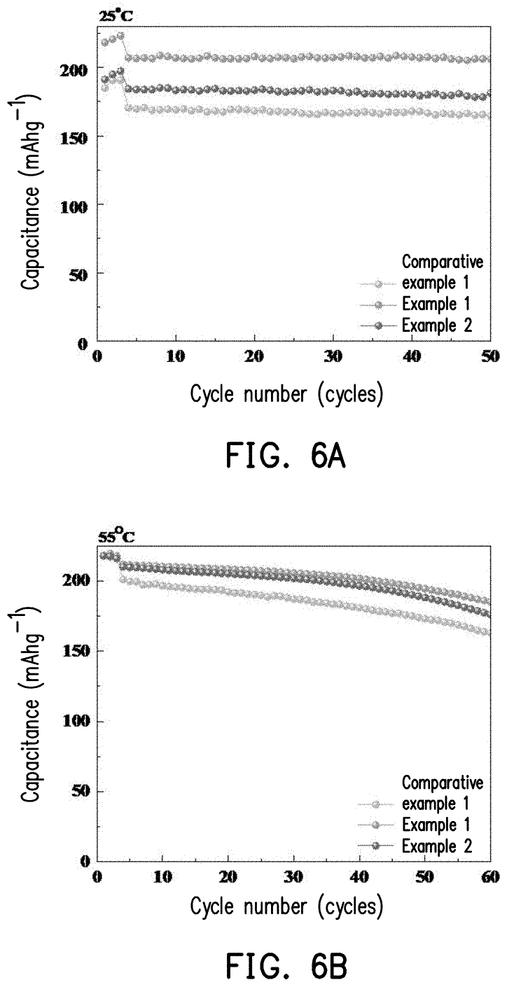

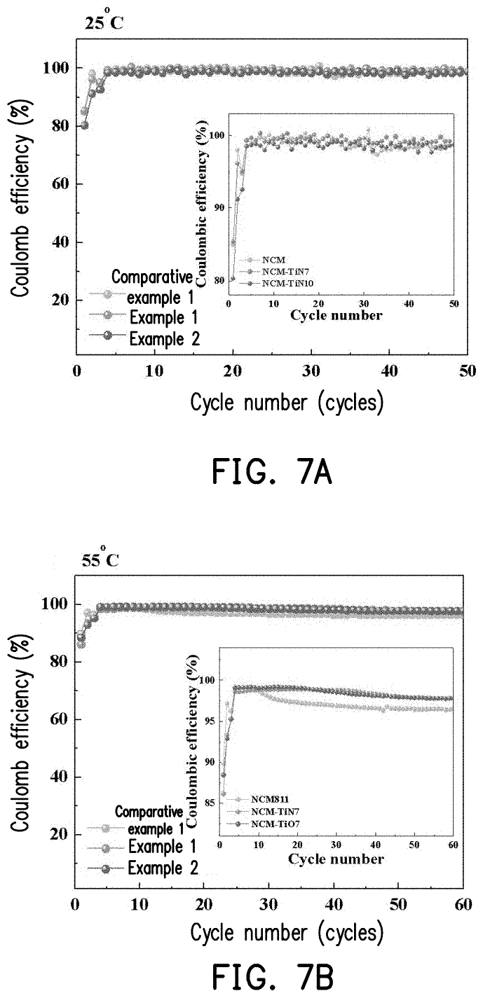

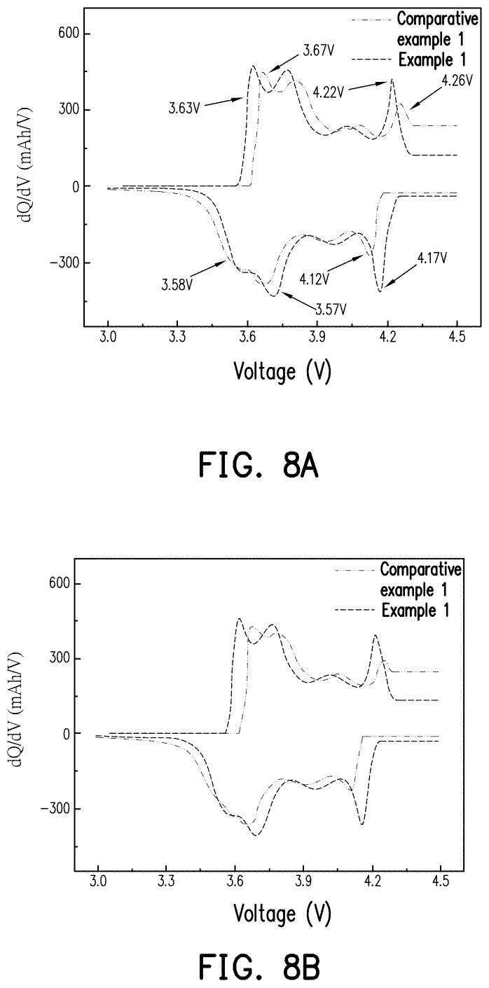

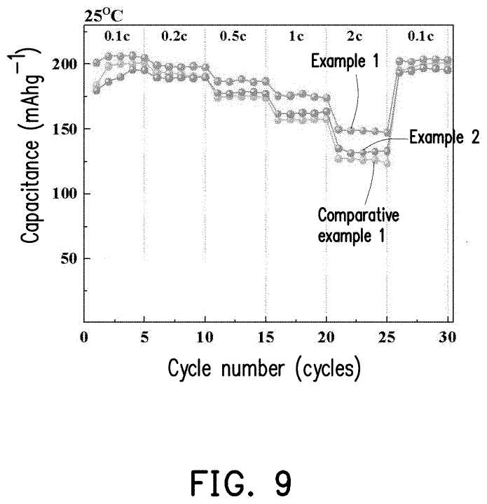

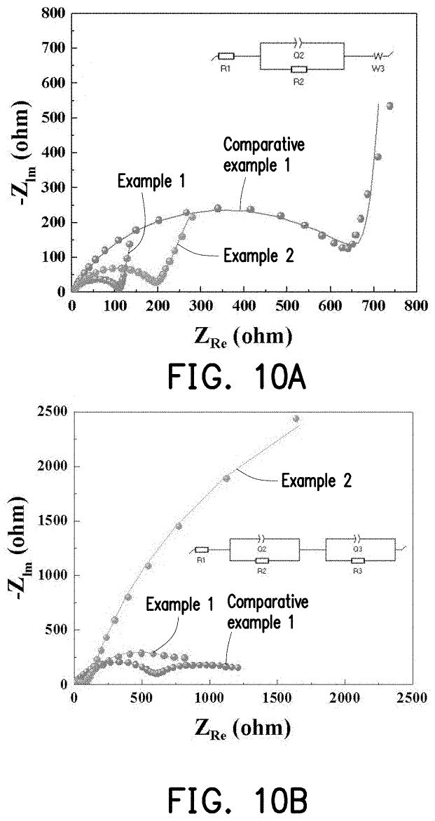

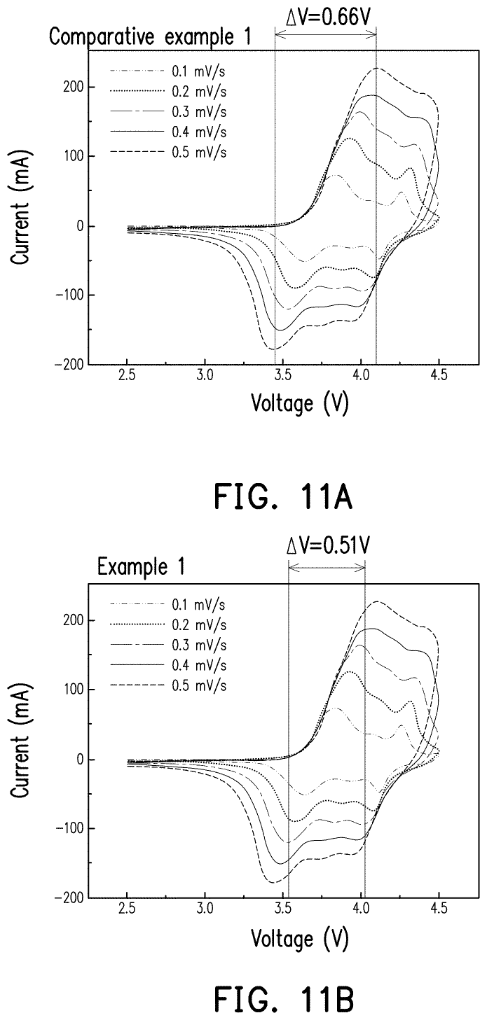

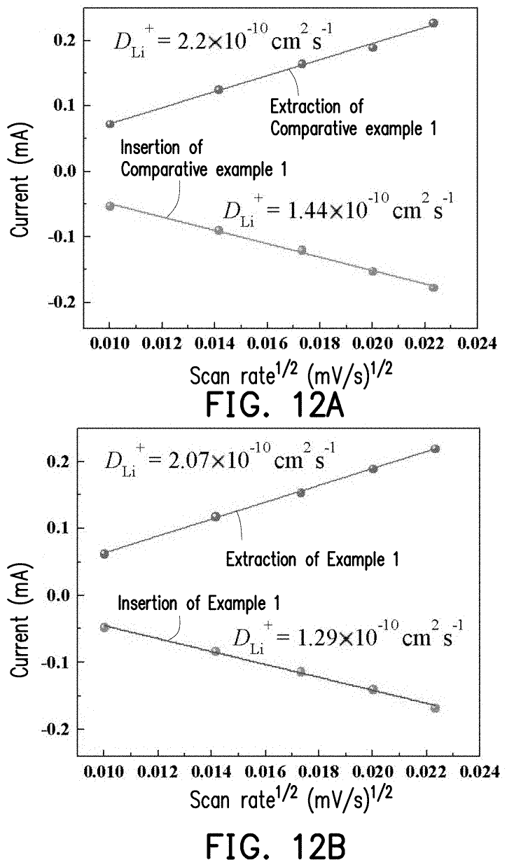

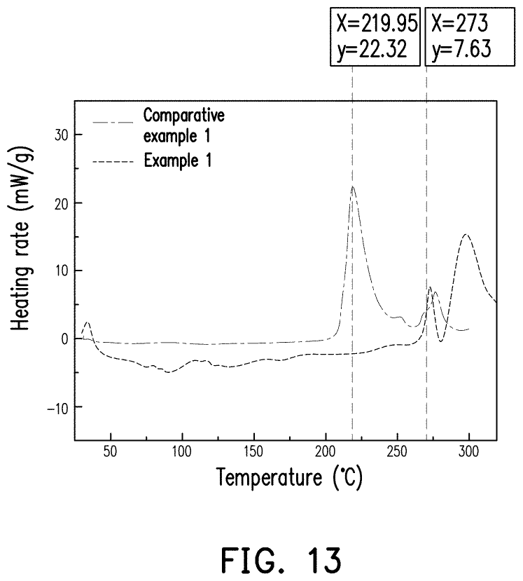

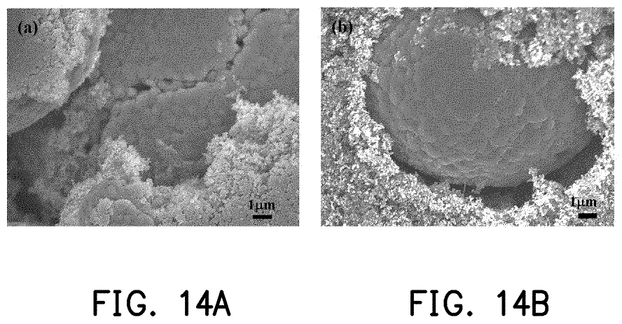

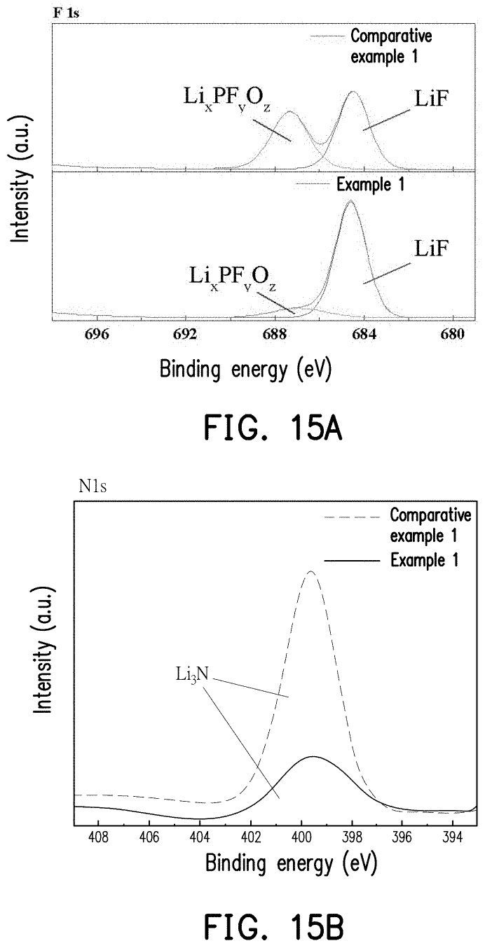

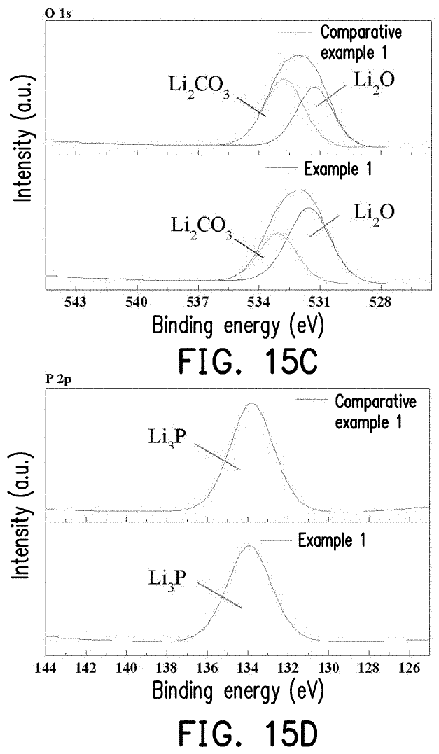

FIG. 2 is an X-ray diffractometer (XRD) diffraction pattern of the Examples and the Comparative example. FIG. 3A and FIG. 3B are transmission electron microscope (TEM) images of an example. FIG. 3C is a line scan enlarged view of the circled portion of FIG. 3B. FIG. 3D is an elemental distribution diagram of the line scan of FIG. 3B. FIG. 4A, FIG. 4B, FIG. 4C, and FIG. 4D are X-ray photoelectron spectroscopy (XPS) (Ti spectrum, N spectrum, C spectrum, O spectrum) surface analysis diagrams of the Examples and the Comparative example, respectively. FIG. 5A and FIG. 5B are graphs of voltage versus capacitance of the Examples and the Comparative example, respectively. FIG. 6A and FIG. 6B are graphs of capacitance versus cycle number of the Examples and the Comparative example, respectively. FIG. 7A and FIG. 7B are graphs of Coulomb efficiency versus cycle number of the Examples and the Comparative example, respectively. FIG. 8A and FIG. 8B are graphs of capacitance and voltage differential (dQ/dV) versus voltage of the Examples and the Comparative example, respectively. FIG. 9 is a graph of capacitance versus cycle number of the Examples and the Comparative example, respectively. FIG. 10A and FIG. 10B are graphs of the imaginary part (Zᵢₘ) versus the real part (Zᵣₑ) of the impedance spectra of the Examples and the Comparative example, respectively. FIG. 11A and FIG. 11B are graphs of current versus voltage of an Example and the Comparative example, respectively. FIG. 12A and FIG. 12B are graphs of current versus scan rate of an Example and the Comparative example, respectively. FIG. 13 is a graph of heating rate versus temperature of an Example and the Comparative example. FIG. 14A and FIG. 14B are scanning electron microscope (SEM) images of the Examples and the Comparative example, respectively. FIG. 15A, FIG. 15B, FIG. 15C, and FIG. 15D are XPS (F spectrum, N spectrum, O spectrum, P spectrum) surface analysis diagrams of the Examples and the Comparative example, respectively.

Hereinafter, with reference to Example 1, Example 2, and Comparative example 1, the efficacy of the lithium battery of the invention will be described in more detail. Moreover, although the following Example 1 and Example 2 are described, without departing from the scope of the invention, the details of the materials used, the procedures and the like may be suitably changed, and the invention should not be limitedly construed by the Examples described below.

### Example 1

In Example 1, 0.8 g of an active substance (LiNi_{0.8}Co_{0.1}Mn0.1O₂), 0.1 g of a conductive additive (carbon black), and 0.1 g of an adhesive (polyvinylidene fluoride) were used to form and coat a slurry on a current collector (aluminum foil), and drying was performed at 120° C. to prepare a positive electrode sheet. Next, the positive electrode sheet was placed in a plasma-assisted physical deposition equipment, and the cavity was evacuated to 10-6 Torr to start air intake (at the same time, argon gas and nitrogen were introduced), the feed flow rate was 30 sccm in both cases, a voltage of 350 volts was applied to a titanium sputtering target, and a plasma treatment process was started to form a titanium nitride protective layer. After 7 minutes, 1M LiPF₆ was used as an electrolyte to form a button lithium battery.

### Example 2

The manufacturing method of the lithium battery of Example 2 is similar to the manufacturing method of the lithium battery of Example 1, and the difference is that after the plasma treatment process was started for 10 minutes, 1M LiPF₆ was used as an electrolyte to form a button lithium battery.

### Comparative Example 1

In Comparative example 1, 0.8 g of an active substance (LiNi_{0.8}Co_{0.1}Mn_{0.1}O₂), 0.1 g of a conductive additive (carbon black), 0.1 g of an adhesive (polyvinylidene fluoride) were used to form and coat a slurry on a current collector (aluminum foil), and after drying, 1M LiPF₆ was used as an electrolyte to form a button lithium battery, wherein the difference between Comparative example 1 and Example 1 is that there is no plasma treatment process (unmodified), and therefore there is no titanium nitride protective layer.

Here, other unexplained compositions and specifications of the lithium battery should be obtained by those of ordinary skill in the art to which the invention pertains according to any content included in the spirit and scope of the appended claims.

The ratio of (003) to (104) diffraction peak intensity calculation of FIG. 2 is shown in Table 1, and the results from Table 1 show that the ratios of Example 1 and Example 2 are both greater than Comparative example 1; and the results from FIG. 3A to FIG. 3D show that the titanium nitride protective layer of Example 1 has a thickness of 1 μm. Moreover, FIG. 4A to FIG. 4D are the test results after placing Example 1, Example 2, and Comparative example 1 in an atmospheric environment for 5 days. From the results shown in FIG. 4A to FIG. 4D, compared with Comparative example 1, the surfaces of Example 1 and Example 2 do have a titanium nitride protective layer.

TABLE 1

| Sample | I₍₀₀₃₎ | I₍₁₀₄₎ | I₍₀₀₃₎/I₍₁₀₄₎ |
|---|---|---|---|
| Example 1 | 3125 | 1392 | 2.245 |
| Example 2 | 4121 | 1671 | 2.466 |
| Comparative | 3185 | 1840 | 1.731 |
| example 1 | | | |

FIG. 5A and FIG. 5B are the results of charging and discharging tests for the first three cycles of Comparative example 1 and Example 1 at room temperature (25° C.), FIG. 6A and FIG. 6B are respectively the cycle performance test results of Example 1, Example 2, and Comparative example 1 at room temperature (25° C.) and high temperature (55° C.), and 7A and FIG. 7B are respectively the Coulomb efficiency test results of Example 1, Example 2, and Comparative example 1 at room temperature (25° C.) and high temperature (55° C.). From the test results of the foregoing figures, it is shown that the lithium batteries of Example 1 and Example 2 have good charge-discharge cycle stability at room temperature and high temperature compared with the lithium battery of Comparative example 1.

FIG. 8A and FIG. 8B are the test results of the twentieth cycle and the fortieth cycle of Comparative example 1 and Example 1 under high temperature (55° C.) conditions, respectively. The results from FIG. 8A and FIG. 8B show that the high-temperature cycle life of the lithium battery of Example 1 is effectively improved compared to the lithium battery of Comparative example 1.

FIG. 9 is the rate performance test results of Example 1, Example 2, and Comparative example 1 at room temperature. The results from FIG. 9 show that the rate performance of the lithium batteries of Example 1 and Example 2 is also increased compared to the lithium battery of Comparative example 1.

FIG. 10A and FIG. 10B are the EIS impedance tests of Comparative example 1, Example 1, and Example 2 before charging and discharging and after the first three cycles of charging and discharging at 0.1 C, respectively. From the results of FIG. 10A and FIG. 10B, it may be seen that the impedance of the lithium batteries of Example 1 and Example 2 is also smaller than that of the lithium battery of Comparative example 1.

FIG. 11A and FIG. 11B are the cyclic voltammetry tests of Comparative example 1 and Example 1 at different scan rates (0.1 mV/s, 0.2 mV/s, 0.3 mV/s, 0.4 mV/s, 0.5 mV/s), respectively, FIG. 12A and FIG. 12B are the Iₚ-v^{1/2} diagrams of each redox peak and the calculated lithium ion diffusion coefficient (D_{Li}⁺) test results of Comparative example 1 and Example 1, respectively, FIG. 13 is the test result of the micro differential scanning calorimeter (DSC) of Comparative example 1 and Example 1 at a heating rate of 10° C./min in an air environment, FIG. 14A and FIG. 14B are pictures of Comparative example 1 (FIG. 14A) and Example 1 (FIG. 14B) after charging and discharging 50 times, respectively, and FIG. 15A to FIG. 15D are the XPS test results of Example 1 and Comparative example 1 after charging and discharging for 50 cycles. The results from the above figures show that, compared with the lithium battery of Comparative example 1, the lithium batteries of Example 1 and Example 2 have significantly improved high-temperature cycle stability, and the thermal stability of electrode materials and battery safety are significantly improved.

Based on the above, via the combination of the positive electrode and the titanium nitride protective layer (formed by the plasma treatment process (physical vapor deposition process)), safety and high-temperature stability of the lithium battery of the invention may be effectively improved while improving performance (such as reduced impedance and improved rate performance) thereof. Moreover, in some embodiments, the active substance may include LiNi_{0.6}Co_{0.2}Mn_{0.2}O₂, LiN_{0.8}Co_{0.1}Mn_{0.1}O₂, LiCoO₂, LiNi_{0.9}Co_{0.05}Mn_{0.05}O₂, LiNi_{0.5}Co_{0.3}Mn_{0.2}O₂, LiFePO₄, xLi₂MnO₃ (1−x)·Li(Co,Ni,Mn)O₂, or a combination thereof. Since nickel has the advantage of high energy density, but at the same time, the higher the content of nickel, the more unstable the lithium battery is, under the design of using the active substance and the titanium nitride protective layer, the protection function of the titanium nitride protective layer may be further highlighted, so that the lithium battery has good stability in both normal-temperature environment and high-temperature environment.

Although the invention has been described with reference to the above embodiments, it will be apparent to one of ordinary skill in the art that modifications to the described embodiments may be made without departing from the spirit of the disclosure. Accordingly, the scope of the disclosure is defined by the attached claims not by the above detailed descriptions.

What is claimed is:

1. A lithium battery, comprising:
a positive electrode, wherein the positive electrode comprises:
a positive electrode sheet comprising an active substance, a conductive additive, a binder, a current collector, or a combination thereof; and
a protective layer disposed on the positive electrode, wherein a material of the protective layer is titanium nitride.

2. The lithium battery of claim 1, wherein the active substance comprises LiNi_{0.6}Co_{0.2}Mn_{0.2}O₂, LiNi_{0.8}Co_{0.1}Mn_{0.1}O₂, LiCoO₂, LiNi_{0.9}Co_{0.05}Mn_{0.05}O₂, LiNi_{0.5}Co_{0.3}Mn_{0.2}O₂, LiFePO₄, xLi₂MnO₃ (1−x)·Li(Co,Ni,Mn)O₂, or a combination thereof.

3. The lithium battery of claim 1, wherein the conductive additive comprises flake graphite, carbon black, carbon nanotubes, graphene, carbon fiber, or a combination thereof, and the adhesive comprises polyvinylidene fluoride, carboxymethyl cellulose, styrene-butadiene rubber, polyimide, polyvinyl alcohol, or a combination thereof, and the current collector comprises aluminum foil.

4. A manufacturing method of a lithium battery, comprising:
providing a positive electrode sheet;
placing the positive electrode sheet into a plasma-assisted physical deposition equipment, wherein the plasma-assisted physical deposition equipment comprises a cavity, and the cavity has a titanium sputtering target;
performing a plasma treatment process on the positive electrode sheet to form a protective layer on the positive electrode sheet, wherein the plasma treatment process comprises:
bombarding the titanium sputtering target with gas ions in the cavity to form titanium ions; and
introducing nitrogen into the cavity to make the titanium ions react with the nitrogen to form the protective layer.

5. The manufacturing method of the lithium battery of claim 4, wherein a process time of the plasma treatment process ranges from 1 minute to 100 minutes.

6. The manufacturing method of the lithium battery of claim 4, wherein a process temperature of the plasma treatment process ranges from 0° C. to 100° C.

7. The manufacturing method of the lithium battery of claim 4, wherein a process pressure of the plasma treatment process is at least less than 0.001 Torr.

8. The manufacturing method of the lithium battery of claim 4, further comprising applying a voltage to the titanium sputtering target to generate a plasma in the cavity to form the gas ions.

9. The manufacturing method of the lithium battery of claim 4, further comprising introducing argon gas into the cavity to generate the gas ions, and a feed flow rate of the argon gas is equal to a feed flow rate of the nitrogen.

10. The manufacturing method of the lithium battery of claim 4, further comprising:
providing a current collector;
coating a slurry on the current collector, wherein manufacturing steps of the slurry comprise:
mixing a solvent with a binder to form a first solution; and
adding a conductive additive and an active substance to the first solution; and
performing a drying process to form the positive electrode sheet.
